(19) United States
(12) Patent Application Publication
(10) Pub. No.: US 2006/0124934 A1
(43) Pub. Date: Jun. 15, 2006

(54) Thin film transistor, production method and production apparatus therefor

(75) Inventors: Yoichi Fukumiya, Yokohama-shi (JP); Tetsuro Saito, Isehara-shi (JP); Tatsumi Shoji, Hiratsuka-shi (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 11/302,275

(22) Filed: Dec. 14, 2005

(30) Foreign Application Priority Data
Dec. 15, 2004 (JP) 2004-363197

(51) Int. Cl. H01L 29/786; H01L 21/84; H01L 21/67

(52) U.S. Cl. 257/66; 438/151; 29/25.01; 438/798

(57) ABSTRACT

A thin film transistor produced through flattening a gate insulating film acquires the high mobility of a carrier, but has a problem of occasionally showing low resistivity, low withstanding voltage, and consequent low reliability. The present invention solves the above described problem and provides a thin film transistor having the high mobility, the high resistivity, the high withstanding voltage and the high reliability. The present invention also provides a method for producing a thin film transistor having a semiconductor film formed on a gate insulating film thereon, which has the steps of: forming the gate insulating film; and flattening a surface of the gate insulating film by irradiating the surface of the gate insulating film with a gas cluster ion beam.

### BACKGROUND OF THE INVENTION

1. Field of the Invention

The present invention relates to a thin film transistor and a production method therefor.

2. Related Background Art

Conventionally, for a semiconductor device for driving a liquid crystal display and a semiconductor device for driving a photovoltaic device, a thin film transistor (TFT: Thin Film Transistor: hereafter abbreviated as TFT) has been used. As for the structure, a coplaner type, a stagger type and a reversed stagger type are proposed.

Such TFTs are required to have various functions according to applications. Particularly, a large screen and a high definition liquid crystal display used in recent years have to write information on one pixel in short time, so that a thin film transistor used therein is absolutely required to improve its writing capability, in other words, to enhance the mobility of a carrier.

Japanese Patent Application Laid-Open No. H06-045605 discloses a method for flattening a gate insulating film at least at an interface contacting with a channel region of a thin film transistor, in order to improve the mobility of a carrier in a reversed stagger type TFT used for the driving device of a liquid crystal flat display.

The method disclosed in the above described patent gazette attains desired flatness, by appropriately setting a film-forming condition in a plasma CVD process employed when forming a silicon nitride film for a gate insulating film.

Another Japanese Patent Application Laid-Open No. H05-013763 discloses a technology for forming a flat and smooth gate insulating film, by forming a film having an etching ratio equal to that of the gate insulating film on the surface of the gate insulating film having unevenness, and by dry etching the formed film.

Another Japanese Patent Application Laid-Open No. H08-120470 describes a method for extremely precisely polishing the surface of a die for molding plastic or glass, and for extremely precisely polishing an optical metal mirror, a glass substrate and a ceramic substrate with a gas cluster ion beam.

A method for producing a thin film transistor according to Japanese Patent Application Laid-Open No. H06-045605 can produce the thin film transistor with the high mobility of a carrier, which originates in the flatness of a silicon nitride film that is a gate insulating film, but has a problem that the obtained thin film transistor may show low reliability because the silicon nitride film contains a low volume ratio of N to Si and consequently has low resistivity and withstand voltage.

In addition, the method for forming a gate insulating film according to Japanese Patent Application Laid-Open No. H05-013763 uses a spin coating technique for coating, for instance, a silanol-based compound on the surface of an insulating film, in the step of flattening the gate insulating film, consequently can not keep an interface between the gate insulating film and a semiconductor layer clean, and occasionally causes the increase of a leakage current or can not give a thin film transistor desired characteristics. The production method has also a problem that the thickness of the gate insulating film is difficult to be controlled, because when the method flattens the gate insulating film by etching it together with a film formed by the spin-coating technique, with a normal dry etching process, the etching rate per minute for a film formed by the spin-coating technique is one or two orders greater than that for the gate insulating film.

For this reason, an object of the present invention is to provide a thin film transistor with the high mobility of a carrier and high reliability, and to provide a production method therefor.

### SUMMARY OF THE INVENTION

In view of the above described problems, the present invention provides a method for producing a thin film transistor including the steps of forming a gate insulating film, and forming a semiconductor film for providing a channel region on the gate insulating film includes the step of flattening a surface of the gate insulating film by irradiating the surface of the gate insulating film with a gas cluster ion beam, after having formed the gate insulating film.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIGS. 1A, 1B, 1C, 1D and 1E are views showing a step of producing a thin film transistor according to the present invention;

FIG. 2 is a view showing a change of surface roughness and the mobility of a carrier when a silicon nitride film has been irradiated with oxygen cluster ions;

FIG. 3 is a view showing a change of surface roughness and the mobility of a carrier when a silicon nitride film has been irradiated with nitrogen cluster ions;

FIG. 4 is a view showing a change of surface roughness and the mobility of a carrier when a silicon oxide film has been irradiated with oxygen cluster ions;

FIG. 5 is a view showing a change of surface roughness and the mobility of a carrier when a silicon oxynitride film has been irradiated with nitrous oxide cluster ions;

FIG. 6 is a view showing a change of surface roughness and the mobility of a carrier when a silicon nitride film has been irradiated with argon cluster ions;

FIG. 7 is a view showing the reduction of a leakage current and the improvement of a breakdown voltage by irradiation with a gas cluster ion beam according to the present invention; and

FIG. 8 is a view showing an apparatus for producing a thin film transistor according to the present invention.

The accompanying drawings, which are incorporated in and constitute a part of the specification, illustrate embodiments of the invention and, together with the description, serve to explain the principles of the invention.

### DETAILED DESCRIPTION OF THE PREFERRED EMBODIMENTS

A method for producing a thin film transistor according to the present invention will be now described with reference to drawings together with steps.

A method for producing a thin film transistor according to the present invention includes irradiating the surface of an insulating film with a gas cluster ion beam, for the purpose of flattening the interface between the insulating film and a semiconductor layer for providing a channel. Various gaseous species can be used for the irradiation with the gas cluster ion beam, but particularly, oxygen, nitrogen or nitrous oxide are preferably used for the irradiation.

When a gas cluster ion beam using oxygen, nitrogen or nitrous oxide for a source gas irradiates an insulating film, it can flatten a gate insulating film, simultaneously can terminate an uncoupled bond on the surface to lower a trap level of an interface, and consequently improves the reliability of a thin film transistor.

An inert gas can be employed for a source gas. In this case, argon, krypton, xenon, or the like can be used, but argon is preferably used because of being inexpensively produced. Alternatively, a combination of gases may be prepared and used by selecting arbitrary gases from the group consisting of oxygen, nitrogen, nitrous oxide, argon, krypton and xenon, and mixing the selected gases. Alternatively, in order to increase cooling efficiency for the purpose of promoting the formation of the cluster, a combination of gases prepared by mixing the above gases with a gas which hardly forms a cluster, such as helium, neon and hydrogen can be occasionally used. A constitution of the present invention will be described in detail in the following embodiments.

### EMBODIMENT 1

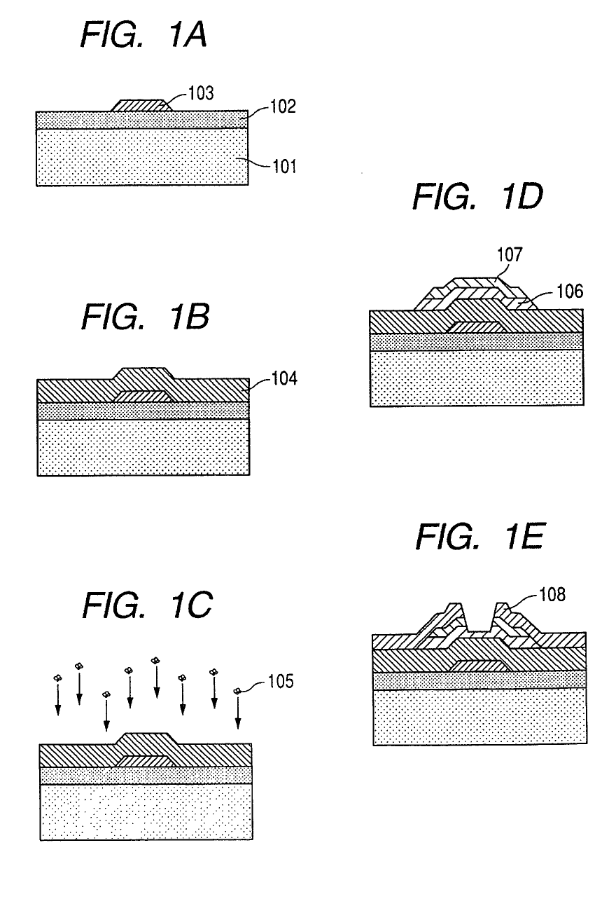

FIGS. 1A, 1B, 1C, 1D and 1E show sectional views for describing a production method according to the present embodiment. In FIG. 1A, a barrier layer 102 and a gate electrode 103 are formed on an insulation substrate 101. The barrier layer is provided as needed, in order to prevent impurities in the substrate from diffusing to an element side. The films are produced by using the normal steps of: forming the barrier layer 102; forming an electroconductive film on the barrier film, which will become a gate electrode 103; and forming the gate electrode 103 by using a normal photolithographic technology. A silicon oxide film or a silicon nitride film is used for the barrier layer, and may have a thickness of about 50 to 200 nm. The usable gate electrode has the film thickness preferably of 50 to 500 nm and more preferably of 70 to 200 nm, and is formed of at least one layer made of an electroconductive material such as Al, Cr, W, Mo, Ti, Ta, AlTi and AlNd.

Subsequently, as shown in FIG. 1B, a silicon nitride film was formed into the thickness of 150 nm for a gate insulating film 104 with a PECVD (plasma enhanced chemical vapor deposition) process. A flowing gas used in the process had a flow ratio of mono-silane, ammonia and nitrogen adjusted to 1:5:35.

For a gate insulating film, silicon nitride is preferable because of having a high dielectric constant, but silicon oxide or silicon oxynitride may be used because of having superior insulating properties. The gate insulating film is not limited to the above described silicon compounds, but may be, for instance, an oxide, a nitride and an oxynitride each of a metal such as tantalum, aluminum, zirconium, hafnium and titanium. Alternatively, the gate insulating film may have a structure in which the various kinds of the above described oxides, nitrides and oxynitrides are arbitrarily layered.

After that, a substrate having a gate insulating film formed thereon was irradiated with a gas cluster ion beam 105. The conditions employed for irradiation with the gas cluster ion beam (hereafter abbreviated as irradiation with GCIB) were the gas of oxygen, the acceleration energy of 5 keV, the dosage of 7×10¹⁵ ions/cm², and the irradiation period of 30 minutes (cf. FIG. 1C).

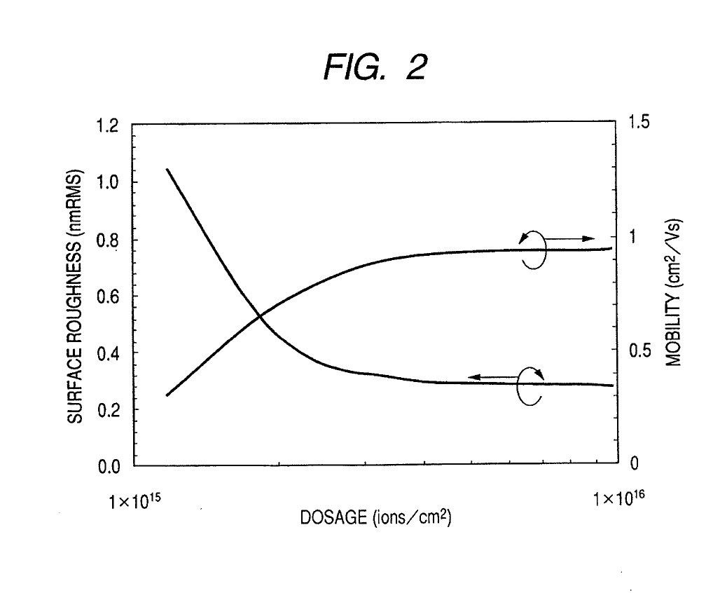

FIG. 2 shows a relationship between a dosage and surface roughness, and a relationship between the dosage and the mobility of a carrier in a thin film transistor formed with the use of the irradiated gate insulating film. The surface roughness is shown as a value of Rms which indicates the surface unevenness measured by using AFM. As for a measurement method for the mobility of the carrier, a generally used method may be used, for instance, a method of measuring the Hall effect is general which occurs when an electric field E and a magnetic field B are applied to the TFT. In the method, the mobility μ of the carrier is calculated by applying the measured result for the Hall Effect to a relational expression of conductivity σ=e·n·μ (e: electron charge) . In the above description, the conductivity σ is a known value determined by a normal measurement method. The surface roughness of a gate insulating film after having been irradiated was 0.28 nm by RMS. In addition, a silicon nitride film of 4 nm deep from the surface was converted to a silicon oxide film.

Subsequently, as shown in FIG. 1D, amorphous hydrogenated silicon was formed into the thickness of 50 nm as a semiconductor film 106, and n+ amorphous hydrogenated silicon doped with phosphor was formed into the thickness of 30 nm as an impurity-doped layer 107, each with a PECVD process.

Other than amorphous hydrogenated silicon, amorphous silicon or polycrystalline silicon can be used for a semiconductor film 106.

In the above description, in the period after a gate insulating film had been formed and before the formation of the semiconductor film was finished, an interface between the insulating film and the semiconductor film was not exposed to the atmosphere.

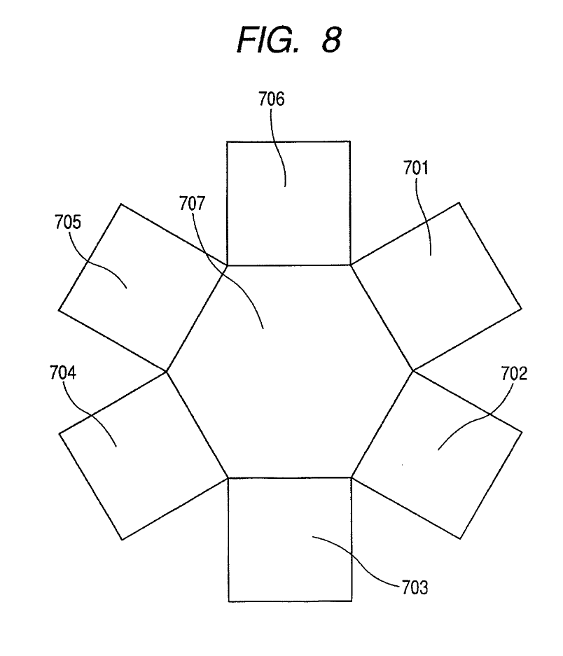

FIG. 8 is a diagrammatic block diagram of an apparatus for producing a thin film transistor without exposing an interface between an insulating film and a semiconductor film to the atmosphere, in a period after the gate insulating film had been formed and before the formation of the semiconductor film was finished. In FIG. 8, reference numerals 701 and 702 denote film-forming chambers, reference numeral 703 denotes a gas cluster ion irradiation chamber, reference numeral 704 an unload lock, reference numeral 705 a load lock, reference numeral 706 a heating chamber and reference numeral 707 a conveying chamber.

As for a configuration of an apparatus for producing a thin film transistor in FIG. 8, the conveying chamber 707 is surrounded by the film forming chambers 701 and 702, the gas cluster ion irradiation chamber 703, the unload lock 704, the load lock 705 and the heating chamber 706. The load lock 705 has a shutter (not shown) to be an entry port for carrying a substrate therein from the outside of the apparatus for producing the thin film transistor (hereafter all the shutters are not shown in the figure), and a shutter to be an outlet for carrying the substrate out into the conveying chamber 707. The unload lock 704 has a shutter to be the entry port for carrying the substrate therein from the conveying chamber 707, and a shutter to be the outlet for carrying the substrate out. Each of the film forming chambers 701 and 702, the gas cluster ion irradiation chamber 703 and the heating chamber 706 other than the unload lock 704 and the load lock 705, which are all arranged around the conveying chamber 707, has a shutter for carrying the substrate in and out between itself and the conveying chamber 707. Furthermore, each of the conveying chamber 707, the film forming chambers 701 and 702, the gas cluster ion irradiation chamber 703, the unload lock 704, the load lock 705 and the heating chamber 706 has a vacuum pump (not shown) for reducing pressure, so as to reduce the pressure in each chamber.

The shutters have a structure capable of hermetically sealing the film forming chambers 701 and 702, the gas cluster ion irradiation chamber 703, the unload lock 704, the load lock 705 and the heat chamber 706 arranged around the conveying chamber 707.

In the next place, a summary of an action of an apparatus for producing a thin film transistor will be described. Each of the film forming chambers 701 and 702, the gas cluster ion irradiation chamber 703, the unload lock 704, the load lock 705, the heating chamber 706 and the conveying chamber 707 has a shutter (entry and outlet of a substrate 101: not shown); and is made airtight so as to be decompressed with a vacuum pump provided for each chamber. Normally, the film forming chambers 701 and 702, the gas cluster ion irradiation chamber 703, the unload lock 704, the load lock 705, the heating chamber 706 and the conveying chamber 707 are decompressed.

In the above description, a carrier device for carrying a substrate is not shown in the figure, but it is needless to say that a normal carrier device can be used.

The load lock 705 has an entry port (not shown) for carrying a substrate 101 having a barrier layer 102 and a gate electrode 103 formed on the surface (hereafter abbreviated as a substrate) from outside, and when the substrate 101 is carried into the load lock 705, the load lock 705 is decompressed with the use of a vacuum pump (not shown), and then the substrate 101 is transported into a conveying chamber through an outlet (not shown) provided in a conveying chamber 707 side of the load lock 705. The transported substrate is transported to the film forming chamber 701 through a shutter provided in a film forming chamber 701, and there a gate insulating film 104 is formed on the surface of the substrate 101. After that, the substrate 101 is transported to a gas cluster ion irradiation chamber 703 from the shutter of the film forming chamber 701 via the conveying chamber 707 and the shutter of the gas cluster ion irradiation chamber 703. There, the surface of the substrate 101 is irradiated with a gas cluster ion, and then the substrate 101 is transported to the film forming chamber 702 from the shutter of the gas cluster ion irradiation chamber 703 via the conveying chamber 707 and the shutter of the film forming chamber 702. There, a semiconductor film 106 and an impurity doped layer 107 are formed on the substrate 101, and after that the substrate is transported to the conveying chamber 707 from the shutter of the film forming chamber 702. Subsequently, the substrate is transported to the unload lock 704 through the entry port of the unload lock 704, the unload lock 704 is pressurized into ambient pressure, and the substrate 101 is carried out from the unload lock 704. By the above steps, the above described gate insulating film 104, the semiconductor film 106 and the impurity doped layer 107 can be formed without exposing the substrate to the atmosphere.

In the above steps, it is preferable to previously heat the substrate to a desired temperature in the heating chamber 706 as needed, before transporting it to the film forming chamber, because a producing period of time is shortened. In addition, it is needless to say that the unload lock 704 is decompressed in a period after the substrate has been carried out and before the next substrate will be carried in.

In addition, though not being shown in a drawing, a configuration is also conceivable which arranges a load lock, a film forming chamber, a gas cluster ion irradiation chamber, a film forming chamber and an unload lock in series in the order. It is needless to say that the configuration can make each chamber perform the each step of forming a gate insulating film, irradiating a substrate with a cluster ion beam, forming a semiconductor film and an impurity doped layer, in the order, while sequentially transporting the substrate to the unload lock from the load lock through each chamber.

In the above configuration of arranging each of the chambers in series, a film forming chamber and a gas cluster ion irradiation chamber are directly connected, but it is also possible to install a decompression chamber between chambers and transport a substrate after having exhausted a gas, as in the case of having installed a conveying chamber.

Finally, as shown in FIG. 1E, a source-drain electrode 108 was formed to prepare a bottom-gate type thin film transistor.

A thin film transistor formed in such a process had a flat and clean interface between a gate insulating film and a semiconductor film, and as a result, showed improved mobility as shown in FIG. 2. In the present embodiment, the ion cluster beam with a dosage of 7×10¹⁵ ions/cm² was used for irradiation. The dosage for irradiation is preferably 5×10¹⁵ ions/cm² or more in order to homogenize the surface of the gate insulating film, and is preferably set to 1×10¹⁶ ions/cm² or less, which is an upper limit, because the dosage more than 1×10¹⁶ ions/cm² needs irradiation for about one hour in the case of having employed acceleration voltage of 5 keV for instance, though depending on incidence energy, and causes an inadequate throughput.

Thus set dosage can improve the mobility of a carrier in a thin film transistor to 0.8 cm²/V·s or higher, impart a thin film transistor high performance, and give it improved reliability because the N/Si ratio of a silicon nitride film increases.

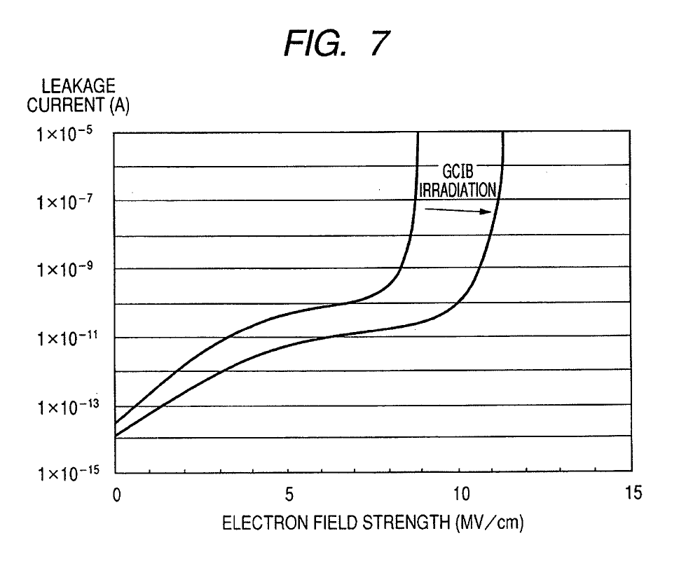

Furthermore, the dosage converted the region of 4 nm deep from the surface of a silicon nitride film to a silicon oxide film, improved insulation properties of the silicon nitride film without lowering a dielectric constant (cf. FIG. 7), and consequently improved the reliability of a TFT.

In the embodiment described below, the silicon nitride film showed the improvement in insulation properties after having been irradiated with a GCIB, as in the case of the present embodiment.

Here, a gas cluster ion beam will be described. In a gas cluster ion beam a cluster is formed of several hundreds to several thousands of aggregated atoms or aggregated molecules, which are gaseous in atmospheric temperature, and the gas cluster is ionizied and accelerated with acceleration voltage.

The gas cluster ion beam has equal total energy to a normal ion beam (monomer), but has an extremely larger mass and momentum while each atom (molecule) has lower energy than a normal ion beam (monomer) has, and can impart a workpiece higher flatness than the normal ion beam can, because of having an effect of laterally sputtering the workpiece as well when having collided with it.

### EMBODIMENT 2

In the present embodiment, the same description as in Embodiment 1 will be omitted.

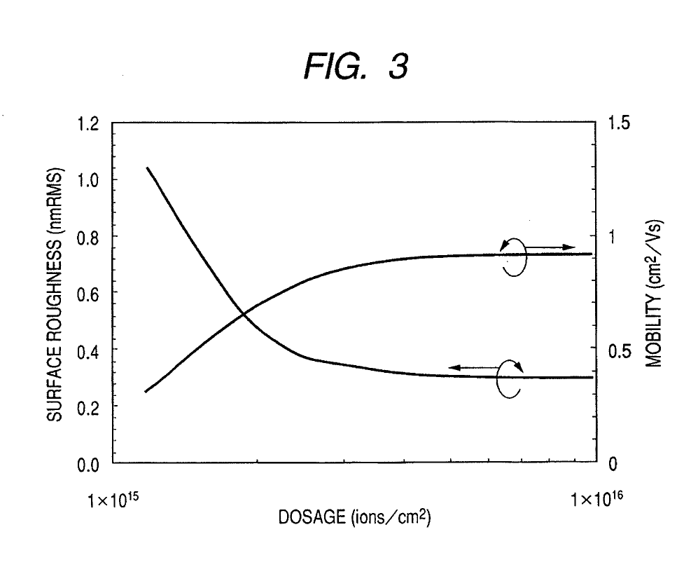

In the present embodiment as well, a thin film transistor is formed by the steps as described in FIGS. 1A, 1B, 1C, 1D and 1E. In the present embodiment, nitrogen is used for a gas cluster ion as a gaseous species. A substrate having a gate insulating film formed thereon was irradiated with nitrogen cluster ions accelerated into the energy of 5 keV at the dosage of 7×10¹⁵ ions/cm² (cf. FIG. 3), in a gas cluster ion beam irradiation chamber. The gate insulating film showed the surface roughness of 0.3 nm by RMS after having been irradiated.

The thin film transistor produced with the above described method showed an improved mobility of a carrier, because of having a flat and clean interface between a gate insulating film and a semiconductor film; and showed improved reliability because the N/Si ratio of a silicon nitride film increased. The improvement in the reliability is particularly caused by the increase of the N/Si ratio on the surface of the silicon nitride film, by irradiation with a gas cluster ion beam. In the present embodiment, the ion cluster beam with a dosage of 7×10¹⁵ ions/cm² was used for irradiation. The dosage for irradiation is preferably set to the range between 5×10¹⁵ ions/cm² and 1×10¹⁶ ions/cm², in order to homogenize the surface of the gate insulating film.

### EMBODIMENT 3

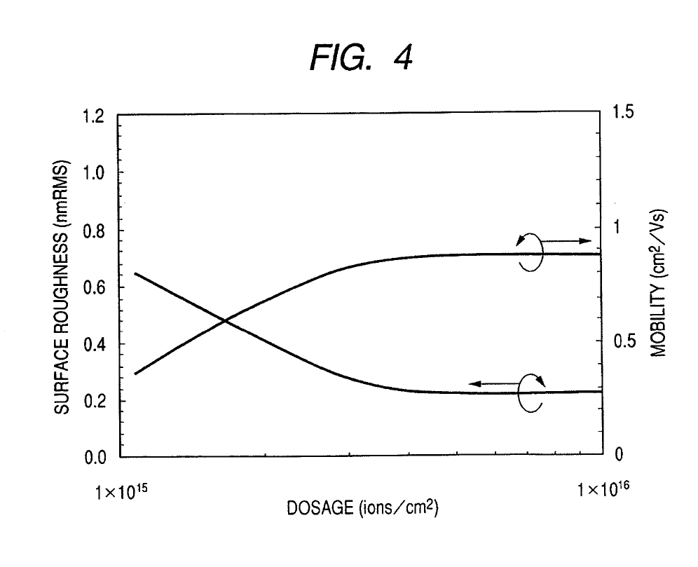

In the present embodiment, a silicon oxide film is used for a gate insulating film. A silicon oxide film was formed as a gate insulating film with a PECVD process which employed TEOS (tetra ethyl ortho silicate) and oxygen as inflow gaseous species and controlled the flow ratio of TEOS to oxygen to 1:20. The formed silicon oxide film had the thickness of 150 nm. After that, a substrate having the gate insulating film formed thereon was irradiated with oxygen cluster ions accelerated to the energy of 5 keV, at the dosage of 7×10¹⁵ ions/cm² (cf. FIG. 4), in a gas cluster ion beam irradiation chamber. The surface roughness of a gate insulating film after having been irradiated was 0.23 nm by RMS.

The thin film transistor produced with the above described method showed an improved mobility of a carrier, because of acquiring a flat and clean interface between a gate insulating film and a semiconductor film; and showed an improved reliability, because the O/Si ratio of a silicon oxide film was enhanced particularly on the interface between the silicon oxide film and the semiconductor film, by irradiation with a gas cluster ion beam. In the present embodiment, the ion cluster beam with a dosage of 7×10¹⁵ ions/cm² was used for irradiation. The dosage for irradiation is preferably set to the range between 6×10¹⁵ ions/cm² and 1×10¹⁶ ions/cm², in order to homogenize the surface of the gate insulating film. Thus set dosage can similarly improve the mobility of a carrier in a thin film transistor to 0.8 cm²/V·s or higher.

### EMBODIMENT 4

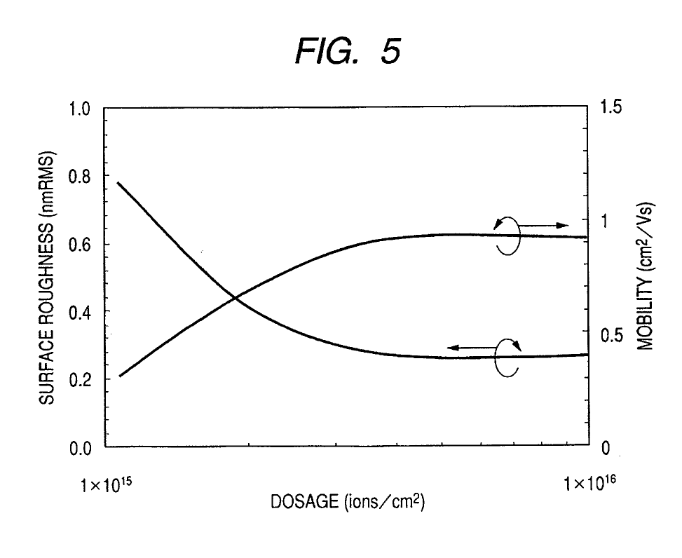

In the present embodiment, a silicon oxynitride film is used for a gate insulating film. The silicon oxynitride film was formed into the thickness of 150 nm as the gate insulating film 104 with a PECVD process. In the process, the flow ratio of mono-silane to nitrous oxide was adjusted to 2:3. After that, a substrate having the gate insulating film formed thereon was irradiated with nitrous oxide cluster ions accelerated to the energy of 5 keV, at the dosage of 7×10¹⁵ ions/cm² (cf. FIG. 5), in a gas cluster ion beam irradiation chamber. The surface roughness of a gate insulating film after having been irradiated was 0.26 nm by RMS.

The thin film transistor produced with the above described method showed an improved mobility of a carrier, because of acquiring a flat and clean interface between a gate insulating film and a semiconductor film; and showed an improved reliability, because the (O, N)/Si ratio of a silicon oxynitride film was enhanced particularly on the surface of the silicon oxynitride film, by irradiation with a gas cluster ion beam. In the present embodiment, the ion cluster beam with a dosage of 7×10¹⁵ ions/cm² was used for irradiation. The dosage for irradiation is preferably set to the range between 5×10¹⁵ ions/cm² and 1×10¹⁶ ions/cm², in order to homogenize the surface of the gate insulating film. Thus set dosage can similarly improve the mobility of a carrier in a thin film transistor to 0.8 cm²/V·s or higher.

### EMBODIMENT 5

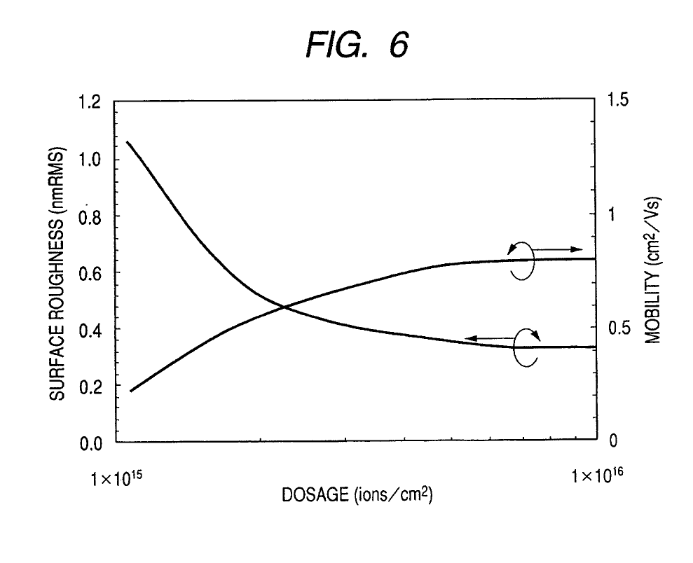

In the present embodiment, argon gas was employed as a gaseous species of a gas cluster ion irradiated on the surface of a gate insulating film, in place of the gaseous species in Embodiment 1. A substrate having a gate insulating film formed thereon was irradiated with argon cluster ions accelerated into the energy of 3 keV at the dosage of 1×10¹⁶ ions/cm² (cf. FIG. 6), in a gas cluster ion beam irradiation chamber. The surface roughness of a gate insulating film after having been irradiated was 0.33 nm by RMS.

Subsequently, as a semiconductor film 106, an amorphous hydrogenated silicon film was formed into the thickness of 50 nm with a PECVD process. Up to this point, an interface between a gate insulating film and a semiconductor film was formed without exposing itself to the atmosphere, while using an apparatus for producing a thin film transistor shown in FIG. 8.

Then, a doped layer 107 and a source-drain electrode 108 were formed to produce a bottom gate type thin film transistor.

The thin film transistor produced with the above described method showed an improved mobility of a carrier, because of having a flat and clean interface between a gate insulating film and a semiconductor film; and showed improved reliability because the N/Si ratio of a silicon nitride film increased. In the present embodiment, the ion cluster beam with a dosage of 1×10¹⁶ ions/cm² was used for irradiation. The dosage for irradiation is preferably set to the range between 7×10¹⁵ ions/cm² and 1.3×10¹⁶ ions/cm², in order to homogenize the surface of the gate insulating film. Thus set dosage can similarly improve the mobility of a carrier in a thin film transistor to 0.8 cm²/V·s or higher.

According to the present invention, clusters which are lumps of aggregated atoms are used as an ion beam for irradiating the gate insulating film in the thin film transistor to flatten it, so that the cluster ion beam does not damage the surface of the gate insulating film because one atom has low energy, lowers a trap level on the interface between the gate insulating film and the semiconductor film, and consequently can improve the reliability of the thin film transistor.

In addition, a configuration of the thin film transistor according to the present invention can be applied not only to a reversed stagger type, but also to the flattening for the interface between the gate insulating film and the semiconductor layer for providing a channel, in the above described coplaner type and the like.

This application claims priority from Japanese Patent Application No. 2004-363197 filed on Dec. 15, 2004, which is hereby incorporated by reference herein.

What is claimed is:

1. A method for producing a thin film transistor having the steps of forming a gate insulating film and forming a semiconductor film for forming a channel region on the gate insulating film, comprising the steps of: forming the gate insulating film; and thereafter flattening a surface of the gate insulating film by irradiating the surface of the gate insulating film with a gas cluster ion beam.

2. The method for producing the thin film transistor according to claim 1, wherein the gate insulating film is made of a compound containing at least one element of nitrogen and oxygen.

3. The method for producing the thin film transistor according to claim 1, wherein a source gas used for the gas cluster ion beam is at least one selected from the group consisting of oxygen, nitrogen, nitrous oxide, argon, krypton and xenon.

4. The method for producing a thin film transistor according to claim 1, wherein, after the gate insulating film has been flattened, the flattened surface is not exposed to the atmosphere.

5. A thin film transistor wherein it is formed with a production method according to claim 1.

6. An apparatus for producing a semiconductor device having a film forming chamber for forming a desired film on a substrate, and a gas cluster irradiation chamber for flattening a surface of the film formed in the film forming chamber, wherein the film forming chamber is coupled with the irradiation chamber.

7. The apparatus for producing a semiconductor device according to claim 6, wherein the film forming chamber is coupled with the irradiation chamber through a conveying chamber for conveying the substrate in a vacuum.
